(19) United States
(12) Patent Application Publication
(10) Pub. No.: US 2010/0052701 A1
(43) Pub. Date: Mar. 4, 2010

(54) Nanoscale Displacement Transducer

(75) Inventor: Youngtack Shim, Seoul (KR)

Correspondence Address: OMIKRON IP LAW GROUP, 16325 Boones Ferry Rd., SUITE 204, LAKE OSWEGO, OR, 97035, US

(73) Assignee: SEOUL NATIONAL UNIVERSITY INDUSTRY FOUNDATION, Seoul (KR)

(21) Appl. No.: 12/198,688

(22) Filed: Aug. 26, 2008

(51) Int. Cl. G01B 7/14; G01R 27/26; G01B 11/14

(52) U.S. Cl. 324/662; 356/625; 702/158; 977/956; 977/773

(57) ABSTRACT

Embodiments of the invention relate to nanoscale measurement of displacement. In one embodiment, a measurement apparatus includes a first plurality of nanoparticles coupled to a first substrate electrically coupled to a second plurality of nanoparticles coupled to a second substrate with a guide or guides disposed between the first substrate and the second substrate that allow for the substrates to move relative to each other.

### BACKGROUND

1. Technical Field

The present disclosure relates generally to the measurement of system parameters and, more specifically, to the nanoscale measurement of displacement.

2. Information

Nanotechnology is an important field of endeavor that provides materials and devices in nanoscale that may be used in a wide variety of applications. In the implementation of nanoscale materials and devices, it may be useful to sense and measure various parameters, such as displacement. Further, it may be advantageous to sense and measure parameters with sensitivity such that small magnitudes may be measurable.

### BRIEF DESCRIPTION OF THE DRAWINGS

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the figures, may be arranged, substituted, combined, and designed in a wide variety of different configurations, all of which are explicitly contemplated and made part of this disclosure.

FIG. 1 is a perspective view of an illustrative embodiment of a nanoscale measurement device.

FIG. 2 is a side view of an illustrative embodiment of a nanoscale measurement device.

FIG. 3 is a diagram of an illustrative embodiment of a nanoscale measurement system.

FIG. 4 is a cross-sectional side view of an illustrative embodiment of a nanoscale measurement device.

FIG. 5 is a cross-sectional side view of an illustrative embodiment of a nanoscale measurement device with a displacement applied.

FIG. 6 is a top-down view of an illustrative embodiment of a nanoscale measurement device.

FIG. 7 is a top-down view of an illustrative embodiment of a nanoscale measurement device with a displacement applied.

FIG. 8 is a side view of an illustrative embodiment of a nanoscale measurement system.

FIG. 9 is a cross-sectional side view of an illustrative embodiment of a nanoscale measurement device.

FIG. 10 is a diagram of an illustrative embodiment of a method.

FIG. 11 is a diagram of an illustrative embodiment of a method.

FIG. 12 is a diagram of an illustrative embodiment of a method.

### DETAILED DESCRIPTION

In the following description, various embodiments will be disclosed. However, it will be apparent to those skilled in the art that the embodiments may be practiced with all or only some of the disclosed subject matter. For purposes of explanation, specific numbers and/or configurations are set forth to provide a thorough understanding of the embodiments. However, it will also be apparent to one skilled in the art that the embodiments may be practiced without one or more of the specific details, or with other approaches and/or components. In other instances, well-known structures and/or operations are not shown or described in detail to avoid obscuring the embodiments. Furthermore, it is understood that the embodiments shown in the figures are illustrative representations and are not necessarily drawn to scale.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

References throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner. Various operations may be described as multiple discrete steps in turn, in a manner that is most helpful in understanding the claimed subject matter. However, the order of description should not be construed as to imply that these operations are necessarily order dependent.

This disclosure is drawn, inter alia, to nanoscale measurement devices and apparatuses, methods for measuring displacement, and related nanoscale systems are described.

In an embodiment, a nanoscale measurement device may include a first plurality of nanoparticles coupled to a substrate surface by optional couplers. The device may also include a second plurality of nanoparticles coupled to another substrate surface by optional couplers. The first plurality of nanoparticles may be spaced such that they electrically contact each other or such that they have small gaps that may be tunneled by electrons. In either case, electrical continuity across the first plurality of nanoparticles may be provided. The second plurality of nanoparticles may be similarly situated to provide electrical continuity across the second plurality of nanoparticles. The first and second pluralities of nanoparticles may face each other and may be held such that they have an electrical coupling by a guide or guides disposed between the surfaces of the first and second substrates that may allow the substrates to move, slide or rotate relative to each other. Electrical contact to the first and second pluralities of nanoparticles may be made by electrodes. One electrode may contact the first plurality of nanoparticles at one end of the device and another electrode may contact the second plurality of nanoparticles at an opposite end of the device. The electrodes may be coupled to a sensing device that may measure an electrical voltage developed across the device or a current flowing therein to measure characteristic resistances of the nanoscale measurement device.

In operation, the substrates may be movingly coupled such that they may be moved or displaced relative to each other. Such movement may change the number of nanoparticles from the first plurality and the second plurality that may be immediately adjacent to or contacting each other. That is, the amount or number of overlapping or contacting nanoparticles may change. That change in overlap or contact may change a characteristic resistance or capacitance of the device, which may be probed or detected by the sensing device. The sensing device may use the resistance or capacitance to determine a displacement measurement. In one embodiment, the pluralities of nanoparticles may be substantially aligned in rows with the rows in the first plurality substantially parallel to the rows in the second plurality. In other embodiments, the pluralities of nanoparticles may be substantially aligned in rows, and the rows in the first plurality may be set at an angle with respect to the rows in the second plurality. Such a configuration may allow displacement measurements that may be smaller than the size of the nanoparticles in the device.

In other embodiments, a light emitter and a detector may be provided and an optical characteristic of the measurement device may be used to determine a displacement measurement. The light source may irradiate the measurement device and the detector may receive resultant light rays. The light rays may be transmitted through the device, for example. The resultant light rays may be monitored for, for example, a polarization change, an intensity change or a diffraction pattern. The monitored parameter may relate to a change in an optical property of the device due to a change in the number of overlapping or contacting nanoparticles, which may be correlated to a linear or angular displacement measurement. In some examples, the light source and the detector may be used without the electrodes and electrical sensor, and in other examples, they may be used with the electrodes and a sensor.

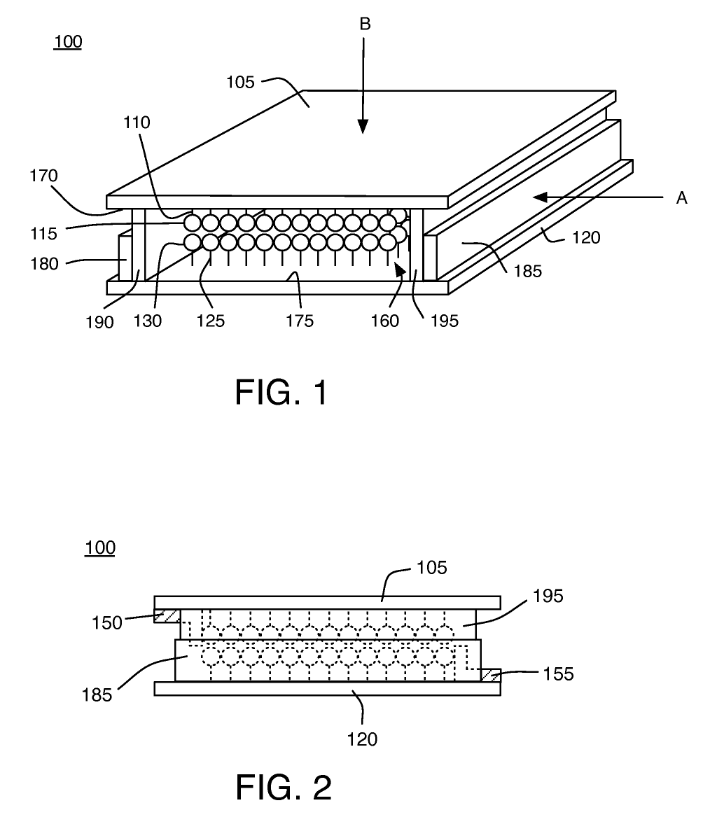

Turning now to FIG. 1 and FIG. 2, an embodiment will be described. As illustrated in FIG. 1, a measurement device 100 may include a substrate 105, couplers 110, nanoparticles 115, a substrate 120, couplers 125, nanoparticles 130 and a guide structure or structures that may include guides 180, 185, 190, 195. FIG. 2 illustrates view A with objects behind guides 185, 195 shown in hatched lines. As shown in FIG. 2, measurement device 100 may include electrodes 150, 155, which may make electrical contact to the nanoparticles. The electrodes are not shown in FIG. 1 for the sake of clarity. Also, FIG. 1 illustrates a column 160 of nanoparticles extending back into the device. It is understood that the other nanoparticles along the illustrated front row of nanoparticles may also be a part of columns that extend back into the device. Those columns are not shown for clarity.

As shown, nanoparticles 115 and nanoparticles 130 may be held apart at a preset distance. In other embodiments, nanoparticles 115 may be in contact with nanoparticles 130. Nanoparticles 115 may be configured to provide electrical continuity among nanoparticles 115, and nanoparticles 130 may be similarly configured to provide electrical continuity among nanoparticles 130. In some examples, the electrical continuity may be provided by the nanoparticles being spaced densely enough to provide direct electrical contact. In other examples, there may be gaps between the nanoparticles that may be quantum mechanically tunneled by electrons such that electrical continuity may be provided. In other embodiments, nanoparticles 115 and nanoparticles 130 may be configured such that no electrical contact is made among the nanoparticles. In such examples, the nanoparticles may be arranged to provide measurable optical properties. Nanoparticles 115 and nanoparticles 130 may have electrical or optical characteristics, such as, for example, their densities, material types, arrangements, or the like, that may be probed via the electrodes. In some embodiments, the nanoparticles may include conductive materials and in other embodiments, the nanoparticles may include dielectric materials.

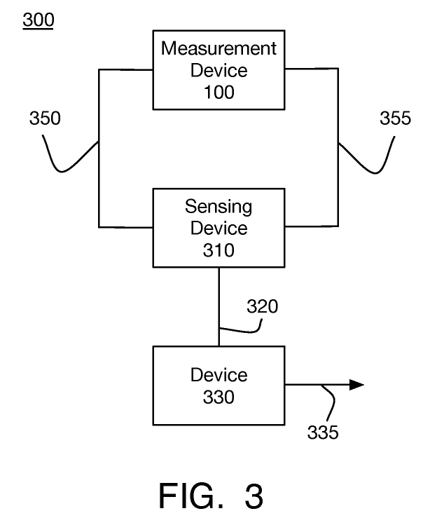

Referring now to FIG. 3, measurement device 100 may be electrically coupled to a sensing device 310 by connectors 350, 355 as a part of a system 300. Connector 350 may be electrically coupled to electrode 150 and connector 355 may be electrically coupled to electrode 155. Connectors 350, 355 may be provided in a variety of configurations, such as, but not limited to, discrete wires or as conductive traces on a substrate or circuit board. As discussed, the substrates of measurement device 100 may move relative to one another and, therefore, the connectors or the electrodes may include slack or conductive couplings that may slide or move to provide moveable electrical connection to the device. Sensing device 310 may be considered a part of a nanoscale measurement device or it may be considered separate from the measurement device.

Sensing device 310 may electrically probe measurement device 100 using the connectors and electrodes to determine an electrical characteristic. In one example, sensing device 310 may include a voltage source and a current measuring device. In another example, sensing device 310 may include a current source and a voltage measuring device. Sensing device 310 may include multiple voltage sources and/or current sources. Sensing device 310 may also include a processor, a memory, and related circuitry that may provide control over a sensing pattern and memory for data storage. Using the provided voltage and measured current (or provided current and measured voltage), a characteristic resistance of the measurement device may be determined. Alternatively, a characteristic capacitance may be determined. In an embodiment, a capacitance may be provided with conductive nanoparticles and an insulator, such as, but not limited to, air between the conductive nanoparticles. In another embodiment, a capacitance may be provided with dielectric nanoparticles. In other embodiments, measurement system 100 may be supplied with a voltage or current by an external source, and sensing device 310 may not include a voltage source or a current source. As discussed, connector 355 may couple to one set of nanoparticles while connector 350 may couple to another set of nanoparticles. Connector 350 may be coupled to one side of a voltage or current source and connector 355 may be coupled to another side of the voltage or current source, such that a closed circuit may be provided. The closed circuit may include, in series, one side of the voltage or current source, connector 350, electrode 150, nanoparticles 115, nanoparticles 130, electrode 155, connector 355, and the opposite side of the voltage or current source. By measuring an electrical characteristic, such as a resistance, of the circuit a sensitive measurement of displacement may be obtained. In other embodiments, different circuit configurations may be provided that may allow sensing device 310 to electrically probe measurement device 100.

When a displacement is applied to measurement device 100, along or about an axis of movement for example, the configuration of the device may change such that the electrical characteristics of the device change. Those changes may be correlated to determine a displacement measurement.

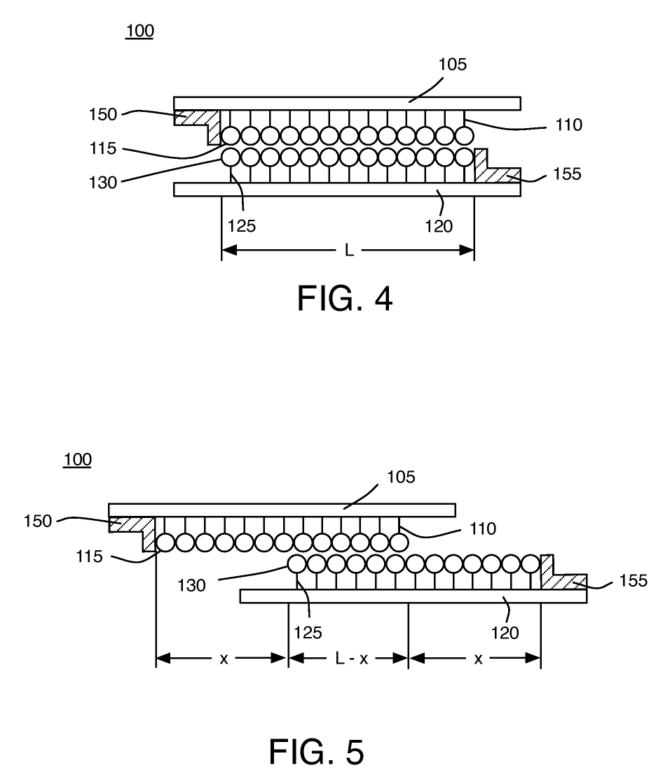

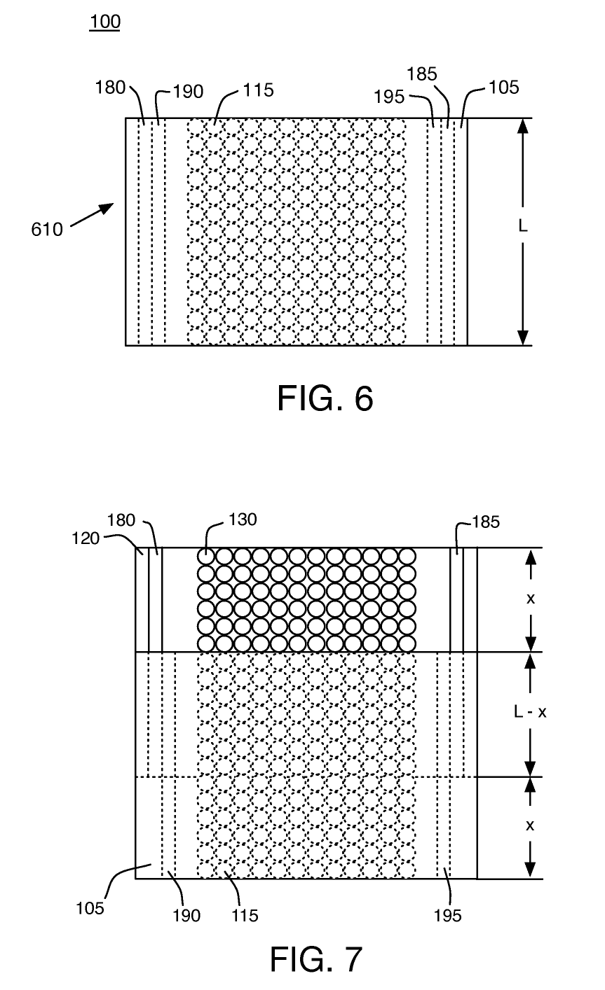

With reference to FIGS. 4-7, operations of the measurement device according to an embodiment will be described. FIG. 4 illustrates view A of measurement device 100 (please refer to FIG. 1), and FIG. 5 illustrates an embodiment of the measurement device with a similar view when a movement or displacement has been made to the device. FIG. 6 illustrates view B of measurement device 100 (see FIG. 1) showing a center portion 610 of the device, and FIG. 7 illustrates an embodiment of the measurement device with a similar view when a movement or displacement has been made to the device. In FIG. 6 and FIG. 7, only a center portion 610 of the measurement device is shown for clarity.

In the embodiment illustrated, a force may have been applied to substrate 105 while substrate 120 may be anchored or secured to cause the displacement, or a force may have been applied to substrate 120 while substrate 105 may be anchored or secured. The displacement may cause relative movement of the substrates that may cause the amount or number of nanoparticles 115 overlapping or contacting nanoparticles 130 to change. That is, the number or amount of nanoparticles 115 that may be immediately adjacent to or contacting nanoparticles 130 may decrease. As shown, the number, amount or area of overlapping nanoparticles may be represented by a length (the width of the overlapping nanoparticles may be substantially constant). In FIG. 4 and FIG. 6, the length representative of the overlap may be L. In FIG. 5 and FIG. 7, the substrates may have moved relative to each other by a distance x, and the length representative of the overlap may be L-x. A greater change in displacement may cause fewer overlapping nanoparticles.

Changes in the device configuration may cause a change in the resistance, capacitance, or other electrical characteristic of the device. For example, a closed circuit using connector 350, coupled to one end of a voltage or current source and connector 355 (please refer to FIG. 3) coupled to an opposite end of the voltage or current source may be used with a current detector or voltage detector to determine a characteristic resistance or capacitance of the device. A resistance, for example, may increase (and the conductivity may decrease) in the example change illustrated. The increased resistance may be due to a decrease in the number or amount of overlapping or immediately adjacent nanoparticles in the circuit.

As discussed, in various embodiments, electrical conductivity between the nanoparticles may be provided by electron tunneling across gaps or by the nanoparticles being densely enough spaced to provide direct electrical connection. Although the nanoparticles may be shown to be in direct contact, no such direct contact may be required for the function of the measurement device. Some examples may include gaps and some may include direct contact. Further, as discussed, in various embodiments, nanoparticles 115 and nanoparticles 130 may be in contact while in other embodiments, they may not contact one another. In an embodiment, although not in contact, an electrical coupling between nanoparticles 115 and nanoparticles 130 may be provided by electron tunneling across a gap between them.

Referring again to FIG. 1 and FIG. 2, other embodiments will be described. As discussed, FIG. 1 and FIG. 2 illustrate measurement device 100, substrate 105, couplers 110, nanoparticles 115, substrate 120, couplers 125, nanoparticles 130, guides 180, 185, 190, 195 and electrodes 150, 155. Substrates 105, 120 may include a wide variety of rigid or semirigid materials including, but not limited to, inorganic materials, silicon, silicon dioxide, ceramics, quartz, organic materials, polymers, or plastics. In general, the substrates may be any material that may maintain its integrity during operation of measurement device 100. In some examples, substrate 105 and substrate 120 may be provided as laminate structures including a plurality of materials stacked in layers. Substrates 105, 120 may include insulating materials such that the substrates do not provide a conduction path. In some examples, substrates 105, 120 may include substantially or partially transparent materials. Substrate 105 and substrate 120 may be the same material or substrate 105 and substrate 120 may be different materials. In general, the materials used for substrates 105, 120 may be chosen based on parameters of the required application such as, but not limited to, the ambient the materials may be subjected to, the displacements to be measured and other material choices within the transducer.

Nanoparticles 115 may be coupled to surface 170 of substrate 105 by optional couplers 110, and nanoparticles 130 may be coupled to surface 175 of substrate 120 by optional couplers 125. Alternatively, nanoparticles 115, nanoparticles 130, or both may be directly mounted to their respective substrates. Nanoparticles 115 and nanoparticles 130 may be any suitable size. In some examples, they may have diameters in the range of approximately 100 to 2,500 nm. In other examples, they may have diameters in the range of approximately 1 to 100 nm. Nanoparticles 115, 130 may include a variety of conductive materials including, but not limited to, copper, silver, gold, nickel, palladium, platinum, tin, lead, aluminum, and alloys thereof. Different materials may be used among nanoparticles 115 or nanoparticles 130 such that the nanoparticles are not necessarily uniform across their entirety. For example, materials of different conductivities may be used across the device in some applications. Nanoparticles 115 and nanoparticles 130 may include uniform conductive materials or they may include nonconductive nanoparticles with conductive coatings. In some embodiments, nanoparticles 115 and nanoparticles 130 may include substantially or partially transparent materials. Nanoparticles 115 and nanoparticles 130 may include the same materials or they may include different materials.

Nanoparticles 115 may be configured to provide electrical continuity among nanoparticles 115, and nanoparticles 130 may be similarly configured to provide electrical continuity among nanoparticles 130. In some examples, the electrical continuity may be provided by the nanoparticles being spaced densely enough to provide direct electrical contact. In other examples, there may be gaps between the nanoparticles that may be quantum mechanically tunneled by electrons such that electrical continuity may be provided. Nanoparticles 115 and nanoparticles 130 may be configured as a conductive tightly packed array or mesh of nanoparticles. Nanoparticles 115, 130 may be evenly or nearly evenly spaced throughout the device as one mesh. Alternatively, the nanoparticles may be spaced at different pitches at different locations of the device. Further, two or more conductive meshes of nanoparticles may be used. The multiple nanoparticle meshes may be provided in series or parallel electrically. In an embodiment, nanoparticles 115 and/or nanoparticles 130 may include dielectric materials.

Nanoparticles 115 and nanoparticles 130 may be organized in columns and rows. In an embodiment, the rows of nanoparticles 115 and the rows of nanoparticles 130 may be substantially aligned, as is shown. In another embodiment, the rows of nanoparticles 115 may be at an angle with respect to the rows of nanoparticles 130. For example, nanoparticles 130 may be aligned parallel to a front edge of the device while nanoparticles 115 are at an angle of, for example, 450, to the front edge of the device. Such row misalignment may allow for the measurement of incremental displacement changes that are smaller than the size of a single nanoparticle of the device. Any non-zero angle may be used, such as, but not limited to, 20° to 70°, 40° to 50, or 1° to 89°.

Optional couplers 110, 125 may include a variety of rigid, semirigid or flexible materials, such as, but not limited to, long chain molecules, molecular assemblies of high aspect ratios, nanotubes, lipids, DNA, RNA, and proteins. Couplers 110, 125 may include insulating materials so as not to provide a conduction path. Couplers 110 may include the same material as substrate 105 and/or couplers 125 may include the same material as substrate 120, such as the sample materials listed above. Couplers 110 may be of approximately the same length as couplers 125 or their lengths may be different. For example, couplers 110 may be longer than couplers 125. Couplers 110 and couplers 125 may be of any suitable length, such as, but not limited to, approximately 10 to 2,000 nm. A single coupler may be included for each nanoparticle or multiple couplers, such as, but not limited to, 2 to 5 couplers, may be provided for each nanoparticle. In some embodiments, couplers 110, 125 may include substantially or partially transparent materials.

As shown, a guide structure including guides 180, 185, 190, 195 may be disposed between surface 170 and surface 175 such that nanoparticles 115 and nanoparticles 130 may be separated by a distance. Guides 180, 185, 190, 195 may be partially elastic or they may be rigid such that they maintain their shape when at least one of the substrates is displaced. The guide structure may take on a variety of configurations. As in the illustrated example, guides 180, 185, 190, 195 may be provided outside or near the periphery of the nanoparticles. In other examples, an additional guide or guides may be provided among the nanoparticles, such as at or near the center of the device. In another example, guides may be provided among the nanoparticles without guides being provided outside or near the periphery of the device.

The guide structure guides may include a variety of materials including, but not limited to, long chain molecules, crooked long chain molecules, molecular assemblies of high aspect ratios, nanotubes, lipids, DNA, RNA, and proteins. In some examples, the guides may include the same material as the substrate materials, as listed above. The guide materials may maintain the integrity of the device upon repeated applications of force to provide for displacement on the device. The guides may be the same materials or they may be different materials. Although the guides may be arranged to be rigid, deformable or elastic guides may be used as long as the guides can guide the substrates during their displacement.

As shown, the guide structure may be configured such that one set of substantially linear guides fits relatively snugly to the side of another set of substantially linear guides. In another example, additional linear guides may be provided, for example outside of guides 180, 185 and attached to substrate 105 or inside of guides 190, 195 and attached to substrate 120 such that one or more guides from one substrate may be sandwiched between guides from another substrate. Also, the illustration shows guides fixedly attached or coupled to both substrates, but in other examples, guides from only one substrate may be provided, and they may fit within trenches or grooves that may be provided in the opposite substrate. Alternatively, substantially linear guides may be provided from one substrate while a grooved attachment guide may be provided on the other substrate such that the linear guide rides or slides within the attachment guide. Also, as shown, the guides may be configured to couple the substrates and provide a sliding motion between them when the are displaced. In other examples, the guides may be balls, ball bearings, discs, cylinders, dumbbell shaped, or molecular aggregates, or the like, and they may couple the substrates to provide a rolling motion between the substrates when they are displaced. In some examples, multiple guide structures may be provided that may be of the same types or of different types.

In some examples, a starting or zero displacement may relate to an entire overlap of nanoparticles 115 and nanoparticles 130 and measured displacement may relate to movement away from that starting position. However, any starting point or position may be used, including partial, little or no overlap and measured displacement may cause an increase or decrease in the amount of overlap. A wide range of options may be available for the implementation of overlaps for the measurement device. For example, a single mesh of nanoparticles 115 and a single mesh of nanoparticles 130 may be used or multiple meshes may be used in a variety of configurations. For example, some meshes may be overlapping at a start point and others may not, and various overlaps may be caused by the device displacement. By measuring the related electrical changes, detailed displacement measurements may be made.

Further, as shown, the nanoparticles may be formed in rows that have substantially the same width across the device. In other embodiments, the rows may have different widths across the device to increase the sensitivity of the device. For example, the nanoparticles may have wedge shapes that face each other such that each move of displacement causes a decrease in the number of overlapping rows and a decrease in the number of overlapping particles in each overlapping row. Other shapes that provide a similar change in the number of overlapping particles, such as diamond shapes, angular shapes or curved shapes may be provided.

As an alternative to the disclosed embodiments that may measure linear displacement, a measurement device may be arranged to measure an angular displacement of at least one of the substrates. To this end, the guide structure may be incorporated in a circular or arcuate arrangement to guide at least one of the substrates along a circular or arcuate path. In an example, the nanoparticles may be provided in different arrangements to accommodate the angular displacement of the substrate and to cause changes in the electrical resistance of the device in response to the force causing the angular displacement.

As shown in FIG. 2 and FIG. 3, nanoparticles 115 may be contacted at one end of the device by electrode 150 and nanoparticles 130 may be contacted at another end of the device by electrode 155. Electrodes 150, 155 may include a variety of conductive materials including, but not limited to copper, silver, gold, nickel, palladium, platinum, tin, lead, aluminum, tungsten, alloys of those materials, or carbon nanowires. Electrode 150 and electrode 155 may include the same materials or they may include different materials. Electrodes 150, 155 may be of a wide variety of shapes or configurations that provide electrical contact to the nanoparticles and allow probing and measurement of their electrical characteristics.

Now with reference to FIG. 3, which illustrates measurement device 100 may be electrically coupled to sensing device 310 by connectors 350, 355 as a part of a system 300, other embodiments will be described. The provided connectors may be used in a wide variety of ways to monitor the measurement device by operation of sensing device 310. For example, a resistance or capacitance using connector 350 and connector 355 may be determined that may be related to a closed circuit running through one end of nanoparticles 130 to an opposite end of nanoparticles 115. As illustrated, two connectors and related electrodes may be provided. In an example, two additional connectors and related electrodes may be provided, connecting nanoparticles 115 and nanoparticles 130 on the opposite ends of the discussed electrodes 150, 155. In other embodiments, more connectors and related electrodes may be used that may correspond to multiple nanoparticle meshes or that may correspond to a variety of locations on the nanoparticle arrays. By configuring the connectors and electrodes and by monitoring different available paths, a wide variety of characteristic data may be used to monitor the relative displacement of the substrates of measurement device 100. By monitoring different electrical characteristics of the device, such as, but not limited to, intralayer and interlayer nanoparticle resistances, and relating them to the device configuration, sensitive measurements of displacement may be made.

Sensing device 310 may output raw electrical data or sensing device 310 may output converted measurement data that may relate to a displacement applied on the measurement device. The converted data may be obtained by correlation using the optional processor and memory of the sensing device. For example, the processor may calculate displacement measurement data using conversion parameters stored in the memory or the processor may use the memory to look up the displacement measurement data based on the measured electrical parameters and preloaded data.

Referring again to FIG. 3, a connector 320 to a device 330 may be provided. Further, an output connection 335 may be provided from device 330. In general, device 330 may be any of a wide variety of devices that may control sensing device 310 and/or utilize output from sensing device 310. Device 330 may include a processor, a memory, input/output devices, display devices, and related circuitry. Device 330 may be provided as a computer or workstation. In some examples, measurement device 100 and sensing device 310 may be provided at a board level and may input/output to device 330 by a pin connection.

As discussed, sensing device 310 may provide raw electrical data or a raw electrical signal to device 330. Device 330 may use the raw data and may correlate it to determine a displacement measurement. Device 330 may use the correlated displacement data in a variety of ways, for example, as a process or system monitor, as feedback to a system, or as a control parameter. Device 330 may provide output over output connection 335 to other devices, databases, or equipment.

FIG. 3 illustrates measurement device 100, sensing device 310 and device 330. However, multiple devices may be used in the system. In particular, it may be useful to provide two or three measurement devices 100 (and, optionally, additional sensing devices and other devices) so that two- or three-dimensional displacement may be measured and used in a system to provide process or system information.

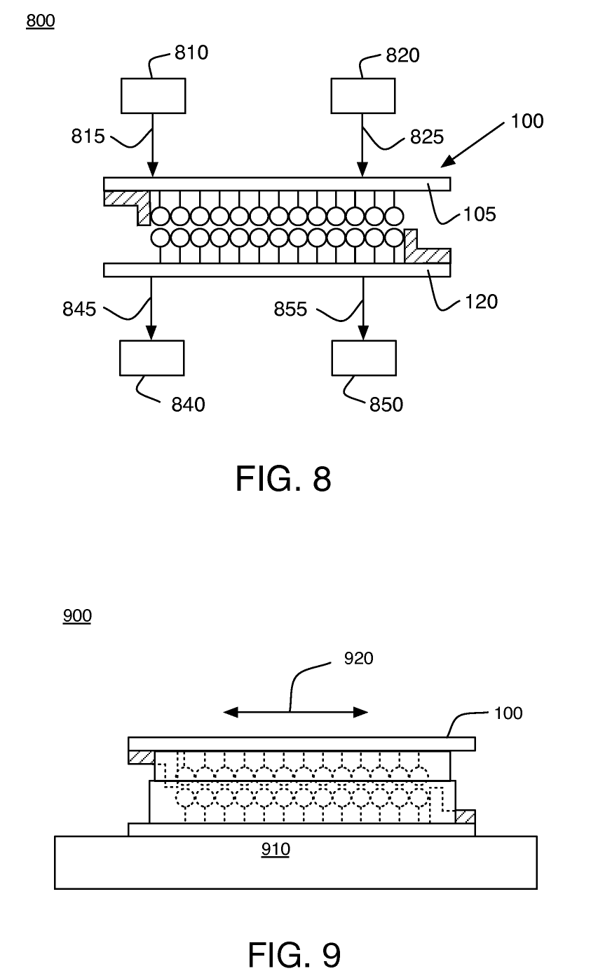

Referring now to FIG. 8, another embodiment will be described. As shown, a measurement system 800 may include measurement device 100, a light source 810, an optional light source 820, a detector 840, and an optional detector 850. Measurement device 100 may include any suitable materials or configurations as described above.

In various embodiments, light source 810 may irradiate the device with light rays 815. In an embodiment, the light rays may pass through the device. Detector 840 may be provided to detect resultant light rays 845 that may have passed through the device. In such an embodiment, substrates 105, 120 may be at least partially transparent and they may substantially transmit light at the wavelength provided. Detector 840 may detect a parameter of the resultant light rays such as, but not limited to, a polarization change, an optical intensity change, a diffraction pattern, or the like. The optical parameter change may relate to a relative displacement of the substrates, as described above, and the change may be correlated to a measurement of linear or angular displacement. In an example, the light source and the detector may be provided substantially aligned opposite the measurement device. In other examples, the light source and the detector may be provided at an angle with respect to a substrate surface of the device.

In some examples, additional sources and/or detectors may be provided. In the illustrated embodiment, light source 820 may irradiate the measurement device with light rays 825 and detector 850 may be provided to receive resultant light rays 855. In various examples, more light sources and/or detectors may be provided. The same number of sources and detectors may be provided or different numbers of sources and detectors may be provided. For example, one detector may receive resultant light rays that may be irradiated on the measurement device from two or more light sources.

In another embodiment, light source 810 and detector 850 may be arranged to irradiate the measurement device and receive resultant light rays that may be reflected off a part of the device. Such resultant reflected rays may be gathered and used to detect a parameter such as, but not limited to, a polarization change, an optical intensity change, a diffraction pattern, or the like. As discussed, the optical parameter change may correspond to a relative displacement change between the substrates of the device, which may be correlated to a measurement of displacement. The reflected rays may reflect off of, for example, couplers 110, nanoparticles 115, nanoparticles 130, couplers 125, or a combination thereof.

In another embodiment, light source 810 may be positioned at one end of the device, and may provide light rays along an axis of the device that may be substantially along the planes of nanoparticles 115, 130. A detector may be positioned at an opposite end of the device to gather the resultant light rays and detect a parameter such as, but not limited to, a polarization change, an optical intensity change, a diffraction pattern, or the like. As discussed, the optical parameter change may correspond to a change in the relative displacement of the substrates of the device, and may be correlated to a measurement of displacement.

The light source or sources and detector or detectors may be used in combination with the described electrodes, sensing device, other devices, and related electrical characteristics measurements or they may be used without the electrodes and related devices. In some embodiments, the electrodes may not be provided. Further, light source 810 may provide any suitable range of wavelength of light based at least in part on the materials chosen for the components of the device. The described detectors may provide raw data, raw electrical signals, or correlated measurements to another device, which may determine a correlated measurement. In some examples, the detector may include a processor and a memory that may be operable to determine correlated measurement, such as, for example, by using a look up table or calculation using preloaded parameters. The detector may also provide output to other devices. The output may be, for example, a process or system monitor, feedback to a system, or a control parameter. In an example, the detector may provide an output to sensing device 210 or device 230 (please refer to FIG. 3).

As discussed, a force may be applied to displace one substrate of the measurement device relative to the other substrate. Referring now to FIG. 9, an embodiment showing measurement device 100 mounted in a package is illustrated. In the example shown, measurement device 100 may be secured to or mounted on a mounting substrate 910, and measurement device may be subject to a force 920. As illustrated, measurement device 100 may be secured by one of the substrates and along an entire length of the device. In other examples, only a portion of the device substrate may be mounted to the mounting substrate. Any support structure or configuration may be used that may allow measurement device 100 to incur relative displacement between its substrates. Additionally, although a horizontal arrangement is shown, measurement device 100 may be mounted at any angle relative to substrate 910, such as vertically. In some examples, sensing device 310 may also be secured or mounted on mounting substrate 910. In some examples, an optical property of the measurement device may be determined, and a sensing device or light source may be provided in the substrate, or a portion of the substrate may be removed to allow light to pass. In other examples, substrate 910 may be substantially or partially transparent, or substrate 910 may include a light guide to irradiate measurement device 100 or to receive resultant light rays.

Force 920 may be exerted on measurement device 100 in any suitable manner. For example, another object may push or pull against the device. In other examples, measurement device 100 may be in a fluid and the fluid may exert a force as it may flow around the device or as it may change pressure in the fluid. Further, although linear or angular displacement measurements have been discussed, measurement device 100 may also be used to measure linear or angular velocity or linear or angular acceleration by measuring a temporal change in the displacement. Therefore, measurement device 100 may be considered a velocimeter or an accelerometer.

As shown, in some embodiments, measurement device 100 may measure linear displacement. In other embodiments, rotational displacement may be measured. For example, substrate 105 and substrate 120 may each be secured to a post running vertically through the device. The post may run approximately through the center of the device, for example. The guides may then be formed in a circular manner around the post such that the substrates may move rotationally around the post. Further, nanoparticles 130 may be provided over a semicircle or half portion of substrate 105 and nanoparticles 115 may be provided over a semicircular or half portion substrate 120. From an example starting point where the nanoparticle portions have a substantial overlap, a rotation may cause a decrease in the overlap, similar to the linear example provided. In other embodiments, more or less than a semicircular or half portion of nanoparticles may be provided. Further, the rotational displacement may be measured from different starting points of overlap with an increase or decrease in the amount of overlap during the rotational displacement.

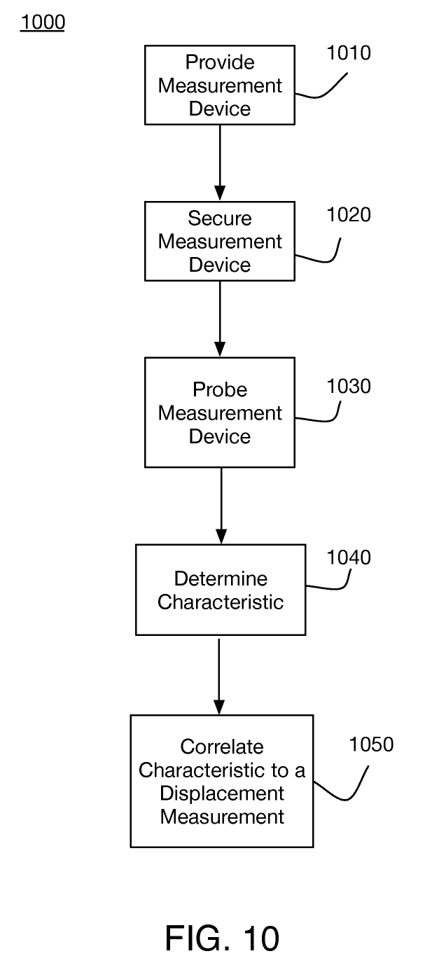

Referring now to FIG. 10, a method 1000 according to an embodiment is illustrated. Method 1000 may provide a nanoscale measurement parameter of, for example, displacement. At block 1010, a measurement device may be provided. Any measurement device as discussed herein may be provided. At block 1020, the measurement device may be secured. The measurement device may be secured in any manner, for example, as shown in FIG. 9 or in the other manners as discussed above. At block 1030, the measurement device may be electrically or optically probed as discussed above. At block 1040, an electrical or optical characteristic may be determined. In an embodiment, the electrical characteristic may include a resistance. In other embodiments, other electrical characteristics, such as those discussed above, including, but not limited to, a capacitance may be determined. In other embodiments, an optical characteristic may be determined. At block 1050, a parameter measurement, such as, but not limited to, a measurement of displacement data may be determined, for example, by correlation with look up data or a conversion calculation, as discussed. In various embodiments, the correlation may be performed by a sensing device, detector, or other device as described. The measurement may be provided to various systems and may be used in a variety of ways, such as, but not limited to, as a process or system monitor, as feedback to a system, or as a control parameter.

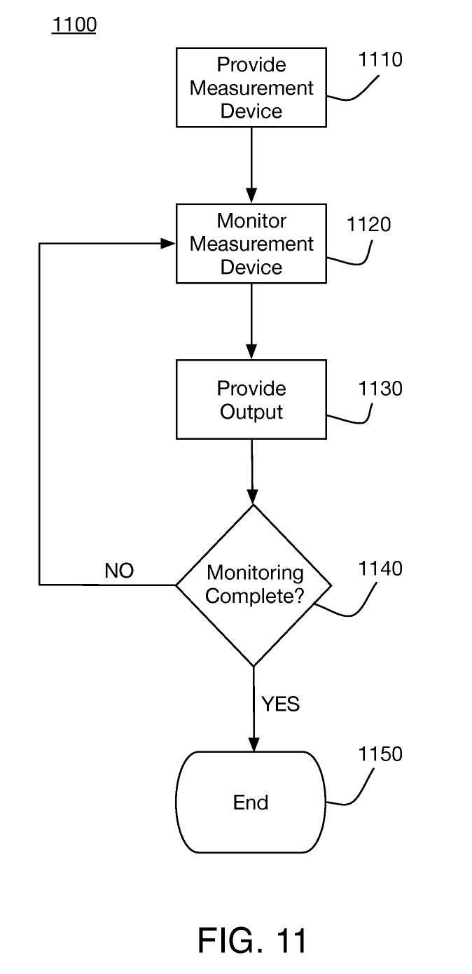

Referring now to FIG. 11, a method 1100 according to an embodiment is illustrated. Method 1100 may provide for continuous or intermittent monitoring of a displacement at nanoscale and continuous or intermittent output of the measured parameters. At block 1110, a measurement device may be provided. Any measurement device as discussed herein may be provided. At block 1120, the measurement device may be monitored, for example using electrical or optical probing as discussed above. At block 1130, an output, such as, but not limited to, a raw electrical signal, raw data, or measurement displacement data may be provided. At decision block 1140, it may be determined whether the monitoring is complete. If the monitoring is complete, then method 1100 may end at end block 1150. If the monitoring is not complete, method 1100 may return to block 1120 for continued monitoring of the measurement device.

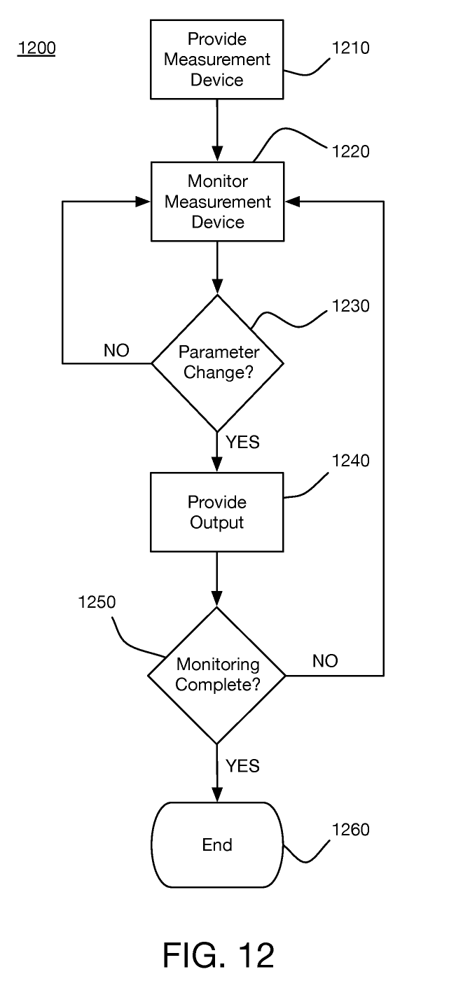

Referring now to FIG. 12, a method 1200 according to another embodiment is illustrated. Method 1200 may provide for continuous or intermittent monitoring of a displacement at nanoscale and output when a change has been detected. At block 1210, a measurement device may be provided. Any measurement device as discussed herein may be provided. At block 1220, the measurement device may be monitored, for example using electrical or optical probing as discussed. At decision block 1230, it may be determined whether there has been a change in the device such that one or more measurement parameters have changed. Whether a change has been detected may be based on a threshold value such that if the displacement change is greater than a threshold, an output may be provided at block 1240. The output may include a raw electrical signal, raw data, or correlated displacement data. If the threshold is not met, no output may be provided and method 1200 may return to block 1220 and the measurement device may be monitored. After providing an output, at decision block 1250, it may be determined whether the monitoring is complete. If the monitoring is complete, then method 1200 may end at end block 1260. If the monitoring is not complete, method 1200 may return to block 1220 for continued monitoring of the measurement device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A nanoscale measurement apparatus comprising:
a first plurality of nanoparticles coupled to a first surface of a first substrate and configured to provide electrical continuity among the first plurality of nanoparticles;
a second plurality of nanoparticles coupled to a second surface of a second substrate and configured to provide electrical continuity among the second plurality of nanoparticles;
a first electrode coupled to the first plurality of nanoparticles;
a second electrode coupled to the second plurality of nanoparticles; and
a guide structure disposed between the first surface of the first substrate and the second surface of the second substrate, the guide structure configured to provide a moveable coupling between the first substrate and the second substrate and to provide an electrical coupling between the first plurality of nanoparticles and the second plurality of nanoparticles.

2. The nanoscale measurement apparatus of claim 1, wherein the guide structure comprises a first guide fixedly coupled to the first surface of the first substrate and a second guide adjacent to the first guide and fixedly coupled to the second surface of the second substrate.

3. The nanoscale measurement apparatus of claim 2, wherein the second guide is adjacent to a first side of the first guide, and the guide structure further comprises a third guide fixedly coupled to the second side of the second substrate and adjacent to a second side of the first guide.

4. The nanoscale measurement apparatus of claim 1, wherein the guide structure comprises at least one of a ball, a ball bearing, a disc or a cylinder.

5. The nanoscale measurement apparatus of claim 1, wherein the guide structure comprises a guide fixedly coupled to the first surface of the first substrate and slidingly coupled to a trench in the second surface of the second substrate.

6. The nanoscale measurement apparatus of claim 1, wherein the first electrode is at a first end of the nanoscale measurement apparatus and the second electrode is at a second end of the nanoscale measurement device.

7. The nanoscale measurement apparatus of claim 1, further comprising:
a sensing device coupled to the first electrode and the second electrode.

8. The nanoscale measurement apparatus of claim 1, wherein the electrical coupling comprises at least one of a conductive coupling or a capacitive coupling.

9. The nanoscale measurement apparatus of claim 8, wherein the sensing device includes a processor and a memory, and wherein the sensing device is configured to provide correlated displacement data.

10. The nanoscale measurement apparatus of claim 1, wherein the first plurality of nanoparticles are coupled to the surface of the first substrate by a plurality of couplers.

11. The nanoscale measurement apparatus of claim 1, wherein the first plurality of nanoparticles includes at least one of copper, silver, gold, nickel, palladium, platinum, tin, lead, or aluminum.

12. The nanoscale measurement apparatus of claim 1, wherein the first plurality of nanoparticles includes first rows of nanoparticles, the second plurality of nanoparticles includes second rows of nanoparticles, and the first rows and the second rows are substantially parallel.

13. The nanoscale measurement apparatus of claim 1, wherein the first plurality of nanoparticles includes first rows of nanoparticles, the second plurality of nanoparticles includes second rows of nanoparticles, and the first rows and the second rows are set at an angle to one another in the range of about 20° to 70°.

14. The nanoscale measurement apparatus of claim 1, wherein the guide structure is configured to provide a linear movement between the first substrate and the second substrate.

15. The nanoscale measurement apparatus of claim 1, wherein the guide structure is configured to provide a rotational movement between the first substrate and the second substrate.

16. A method comprising:
providing a nanoscale measurement device including a first plurality of nanoparticles coupled to a first substrate electrically coupled to a second plurality of nanoparticles coupled to a second substrate by a guide structure configured to provide a moveable coupling between the first substrate and the second substrate;
electrically probing the nanoscale measurement device to determine an electrical characteristic related to a displacement of the first substrate relative to the second substrate; and
correlating the electrical characteristic to a displacement measurement.

17. The method of claim 16, wherein the electrically probing the nanoscale measurement device comprises electrically probing the nanoscale measurement device with a sensing device that includes a voltage supply and a current sensor, and wherein the electrical characteristic is a resistance.

18. The method of claim 17, wherein the correlating the electrical characteristic comprises correlating the electrical characteristic with a processor and a memory of the sensing device.

19. The method of claim 18, wherein the correlating the electrical characteristic comprises looking up the displacement measurement based on the electrical characteristic and preloaded data.

20. The method of claim 18, wherein the correlating the electrical characteristic comprises calculating the displacement measurement using a conversion parameter stored in the memory.

21. The method of claim 17, wherein the correlating the electrical characteristic comprises correlating the electrical characteristic with a second device including a processor and a memory, and wherein the second device receives a raw electrical signal from the sensing device.

22. The method of claim 16, wherein the moveable coupling comprises a linear moveable coupling.

23. The method of claim 16, wherein the moveable coupling comprises a rotational moveable coupling.

24. The method of claim 16, wherein the electrical coupling comprises at least one of a conductive coupling or a capacitive coupling.

25. The method of claim 16, further comprising:
securing the first substrate of the nanoscale measurement device to a mounting substrate; and
applying a force to the second substrate to cause the displacement of the first substrate relative to the second substrate.

26. A system comprising:
a nanoscale measurement device including:
a first plurality of nanoparticles coupled to a first surface of a first substrate and configured to provide electrical continuity among the first plurality of nanoparticles;
a second plurality of nanoparticles coupled to a second surface of a second substrate and configured to provide electrical continuity among the second plurality of nanoparticles;
a first electrode coupled to the first plurality of nanoparticles;
a second electrode coupled to the second plurality of nanoparticles; and
a guide structure disposed between the first surface of the first substrate and the second surface of the second substrate, the guide structure configured to provide a moveable coupling between the first substrate and the second substrate and to provide an electrical coupling between the first plurality of nanoparticles and the second plurality of nanoparticles;
a sensing device coupled to the first electrode and the second electrode; and
a device coupled to the sensing device to receive a signal.

27. The system of claim 26, wherein the signal comprises a raw electrical signal and the device is configured to correlate the raw electrical signal to a displacement measurement.

28. The system of claim 26, wherein the sensing device includes a voltage source, and wherein the first electrode is coupled to a first side of the voltage source and the second electrode is coupled to a second side of the voltage source.

29. The system of claim 28, wherein the sensing device includes a processor and a memory, and the signal includes a displacement measurement.

30. The system of claim 26, wherein the nanoscale measurement device and the sensing device are secured to a mounting substrate, and the device is coupled to the sensing device through a pin connection.

31. A nanoscale measurement apparatus comprising:
a first plurality of nanoparticles coupled to a first substrate and configured to provide electrical continuity among the first plurality of nanoparticles;
a second plurality of nanoparticles coupled to a second substrate and configured to provide electrical continuity among the second plurality of nanoparticles and to form an electrical coupling with the first plurality of nanoparticles to determine an electrical property of the nanoscale measurement apparatus; and
a guide structure disposed between the first substrate and the second substrate and configured to movably maintain a gap between the first substrate and the second substrate, wherein the nanoscale measurement apparatus is configured to change the electrical coupling and the electrical property when an external force moves the first substrate with respect to the second substrate using the guide structure.

32. The nanoscale measurement apparatus of claim 31, wherein the electrical coupling comprises direct contact between the first plurality of nanoparticles and the second plurality of nanoparticles.

33. The nanoscale measurement apparatus of claim 32, wherein the electrical property comprises an electrical conductivity, and wherein the nanoscale measurement apparatus determines at least one of a displacement, a velocity, or an acceleration by monitoring a change in the electrical conductivity.

34. The nanoscale measurement apparatus of claim 31, wherein the second plurality of nanoparticles are spaced apart from the first plurality of nanoparticles and the electrical coupling includes electron tunneling.

35. The nanoscale measurement apparatus of claim 31, wherein the electrical property comprises an electrical capacitance, and wherein the nanoscale measurement apparatus determines at least one of a displacement, a velocity, or an acceleration by monitoring a change in the electrical capacitance.

36. A system comprising:
a nanoscale measurement device including:
a first plurality of nanoparticles coupled to a first surface of a first substrate;
a second plurality of nanoparticles coupled to a second surface of a second substrate; and
a guide structure disposed between the first surface of the first substrate and the second surface of the second substrate, the guide structure configured to provide a moveable coupling between the first substrate and the second substrate;
a light source configured to irradiate light rays onto the nanoscale measurement device; and
a detector configured to detect a change in an optical property of the nanoscale measurement device by monitoring a resultant light ray.

37. The system of claim 36, wherein the detector is configured to detect at least one of a polarization change, an optical intensity change, or a diffraction pattern.

38. The system of claim 36, wherein the light source and the detector are configured to pass the light rays through the first substrate, the first plurality of nanoparticles, the second plurality of nanoparticles, and the second substrate.

39. The system of claim 36, wherein the light source and the detector are configured to pass light rays along an axis substantially planar to the first plurality of nanoparticles.

40. The system of claim 36, further comprising:
a first electrode coupled to the first plurality of nanoparticles;
a second electrode coupled to the second plurality of nanoparticles; and
a sensing device coupled to the first electrode and the second electrode, and configured to monitor an electrical characteristic of the nanoscale measurement device.
